(19) United States
(12) Patent Application Publication
(10) Pub. No.: US 2025/0047076 A1
(43) Pub. Date: Feb. 6, 2025

(54) LASER DIODE COMPONENT AND METHOD FOR PRODUCING AT LEAST ONE LASER DIODE COMPONENT

(71) Applicant: ams-OSRAM International GmbH, Regensburg (DE)

(72) Inventor: Hubert HALBRITTER, Dietfurt (DE)

(73) Assignee: ams-OSRAM International GmbH, Regensburg (DE)

(21) Appl. No.: 18/716,851

(22) PCT Filed: Nov. 16, 2022
(86) PCT No.: PCT/EP2022/082106

§ 371 Date: Jun. 5, 2024

(30) Foreign Application Priority Data
Dec. 7, 2021 (DE) 102021132164.6

(51) Int. Cl. H01S 5/42

(52) U.S. Cl. CPC H01S 5/426

(57) ABSTRACT

The invention relates to a laser diode component including a first semiconductor layer stack which has a first active zone for emitting a first laser radiation, a second semiconductor layer stack which has a second active zone for emitting a second laser radiation, the first and second semiconductor layer stacks following one another in a main emission direction, a resonator which has a first reflective layer and a second reflective layer, and an electrically conductive connecting region which is arranged between the first and second semiconductor layer stacks and has a first connecting layer and a second connecting layer, wherein the first connecting layer is applied to the first semiconductor layer stack, and the second connecting layer is applied to the second semiconductor layer stack. The invention also relates to a method for producing at least one laser diode component.

### CROSS-REFERENCE TO RELATED APPLICATIONS

The present application is a national stage entry from International Application No. PCT/EP2022/082106, filed on Nov. 16, 2022, published as International Publication No. WO 2023/104457 A1 on Jun. 15, 2023, and claims priority to German Patent Application No. 10 2021 132 164.6, filed Dec. 7, 2021, the disclosures of all of which are hereby incorporated by reference in their entireties.

### FIELD

A laser diode component and a method for producing at least one laser diode component are specified. For example, the laser diode component is suitable for emitting coherent radiation, for example in the short-wave, visible spectral range.

### BACKGROUND

One object to be achieved by the present disclosure is, inter alia, to specify a high-performance laser diode component. Another object to be achieved by the present disclosure is, inter alia, to specify an efficient method for producing such a laser diode component.

These objects are achieved, inter alia, by a laser diode component and a method for producing at least one laser diode component with the features of the independent claims.

Further advantages and configurations of a laser diode component and of a method for producing at least one laser diode component are the subject of the dependent claims.

### SUMMARY

According to at least one embodiment of a laser diode component, the laser diode component comprises a first semiconductor layer stack, which comprises a first active zone for emitting a first laser radiation, and a second semiconductor layer stack, which comprises a second active zone for emitting a second laser radiation.

It is possible for the laser diode component to comprise more than two semiconductor layer stacks.

The laser diode component is suitable for continuous and pulsed operation.

The active zones can each comprise a sequence of single layers by means of which a quantum well structure, in particular a single quantum well structure (SQW) or multiple quantum well structure (MQW), is formed.

According to at least one embodiment, the first and second semiconductor layer stacks follow one another in a main emission direction. The first and second semiconductor layer stacks can thus be stacked on top of each other in a main emission direction. The main emission direction denotes a direction in which a substantial part of the laser radiation is emitted from the laser diode component. The laser diode component can have one or more main emission directions.

According to at least one embodiment of a laser diode component, the laser diode component comprises a resonator which comprises a first reflective layer and a second reflective layer. The first reflective layer can be arranged on a side of the first semiconductor layer stack facing away from the second semiconductor layer stack and the second reflective layer can be arranged on a side of the second semiconductor layer stack facing away from the first semiconductor layer stack. The first and second semiconductor layer stacks are thus arranged in a common resonator. For example, the reflective layer arranged on a radiation outcoupling side of the laser diode component may have a lower reflectivity than the reflective layer arranged on a side opposite the radiation outcoupling side. For example, the laser radiation in the present case is to be understood as coherent radiation in the fundamental mode of the resonator. The first and the second laser radiation can have similar or identical wavelengths or similar or identical wavelength spectra.

Due to the plurality of semiconductor layer stacks or the plurality of active zones, an output power of the laser diode component can be increased compared to a laser diode component with a single active zone.

According to at least one embodiment of a laser diode component, the laser diode component comprises an electrically conductive connecting region which is arranged between the first and second semiconductor layer stacks and comprises a first connecting layer and a second connecting layer. For example, the first connecting layer is applied to the first semiconductor layer stack and the second connecting layer is applied to the second semiconductor layer stack. The first and second connecting layers can be directly adjacent to each other. The connecting region is intended for mechanically connecting the individual, i.e. in particular non-monolithically integrated, semiconductor layer stacks to one another. In addition, the connecting region is intended for electrically conductively connecting the semiconductor layer stacks. In particular, the connecting region is free of a tunnel contact. Avoiding a tunnel contact in the connecting region has the advantage of a lower voltage drop, among other things.

Furthermore, the connecting region for the first and the second laser radiation can be designed to be radiation transmissive.

According to at least one embodiment of a laser diode component, the laser diode component comprises:
a first semiconductor layer stack which comprises a first active zone for emitting a first laser radiation,
a second semiconductor layer stack which comprises a second active zone for emitting a second laser radiation, the first and second semiconductor layer stacks following one another in a main emission direction,
a resonator which comprises a first reflective layer and a second reflective layer, the first reflective layer being arranged on a side of the first semiconductor layer stack facing away from the second semiconductor layer stack and the second reflective layer being arranged on a side of the second semiconductor layer stack facing away from the first semiconductor layer stack, and
an electrically conductive connecting region which is arranged between the first and second semiconductor layer stacks and comprises a first connecting layer and a second connecting layer, wherein
the first connecting layer is applied to the first semiconductor layer stack and the second connecting layer is applied to the second semiconductor layer stack.

According to at least one embodiment, the laser diode component is a VCSEL (vertical-cavity surface-emitting laser). In this case, radiation is emitted vertically to a plane of the active zone(s) of the laser diode component.

According to at least one embodiment or configuration, the first and second connecting layers are electrically conductive. Accordingly, the first and second connecting layers may each contain an electrically conductive material or electrically conductive materials. For example, the first and second connecting layers each contain or consist of TCO (transparent conductive oxide).

TCOs are transparent, conductive materials, usually metal oxides such as zinc oxide, tin oxide, cadmium oxide, titanium oxide, indium oxide or indium tin oxide (ITO). In addition to binary metal-oxygen compounds such as ZnO, SnO₂ or In₂O₃, also ternary metal-oxygen compounds such as Zn₂SnO₄, CdSnO₃, ZnSnO₃, MgIn₂O₄, GaInO₃, Zn₂In₂O₅ or IngSn₃O₁₂ or mixtures of different transparent conductive oxides belong to the group of TCOs. Furthermore, the TCOs do not necessarily correspond to a stoichiometric composition and can also be p- or n-doped.

By using TCO for the first and second connecting layers, the first and second semiconductor layer stacks or a first semiconductor layer sequence and a second semiconductor layer sequence, from which the semiconductor layer stacks are produced, can be connected to each other by means of wafer bonding. This bonding technique allows the laser diode component to be produced efficiently.

According to at least one embodiment, the first and second semiconductor layer stacks each comprise a first semiconductor region of a first conductivity type, for example an n-doped semiconductor region, and a second semiconductor region of a second conductivity type, for example a p-doped semiconductor region. The active zone is arranged between the first and second semiconductor regions in each case. For example, the first and second semiconductor regions are arranged alternately in the main emission direction. In other words, a pn-pn- . . . or np-np- . . . structure can be realized in the laser diode component. The connecting region can therefore connect semiconductor regions of different conductivity types. The first and second semiconductor regions can each have a sequence of single layers, some of which can be undoped or lightly doped. The single layers may be layers epitaxially deposited on a growth substrate.

Materials based on arsenide, phosphide or nitride compound semiconductors, for example, can be considered for the semiconductor regions or single layers of the semiconductor layer stacks. “Based on arsenide, phosphide or nitride compound semiconductors” in the present context means that the semiconductor layers contain AlₙGaₘIn₁₋ₙ₋ₘAs, AlₙGaₘIn₁₋ₙ₋ₘP, InₙGa₁₋ₙAsₘP₁₋ₘ or AlₙGaₘIn₁₋ₙ₋ₘN, with 0≤n≤1, 0≤m≤1 and n+m≤1. This material does not necessarily have to have a mathematically exact composition according to the above formula. Rather, it can have one or more dopants as well as additional components that essentially do not change the characteristic physical properties of the AlₙGaₘIn₁₋ₙ₋ₘAs—, AlₙGaₘIn₁₋ₙ₋ₘP—, InₙGa₁₋ₙAsₘP₁₋ₘ— or AlₙGaₘIn₁₋ₙ₋ₘN material. For the sake of simplicity, however, the above formula only contains the essential constituents of the crystal lattice (Al, Ga, In, As or P or N), even if these may be partially replaced by small amounts of other substances. A quinternary semiconductor consisting of Al, Ga, In (group III) and P and As (group V) is also conceivable.

According to at least one embodiment or configuration, at least one of the two semiconductor layer stacks is essentially free of a growth substrate. The growth substrate can be at least thinned or completely removed in the course of the production, so that at most a small part of the growth substrate remains on the semiconductor layer stack. In other words, at least one of the two semiconductor layer stacks can be a thin-film structure. In particular, the growth substrate is at least partially removed from the second semiconductor layer stack. Furthermore, the growth substrate may also be at least partially removed from the first semiconductor layer stack. However, it is also possible for the growth substrate to remain on the first semiconductor layer stack and for the radiation to be coupled out through the growth substrate.

According to at least one embodiment or configuration, the connecting region is arranged at a node of a standing wave formed in the resonator. This allows the absorption of the radiation in the connecting region to be reduced.

The resonance condition for the formation of standing waves with reflective layers arranged essentially parallel to each other is: n*λ/2=L, where n is an integer, λ is the wavelength of the laser radiation, i.e. the first or second laser radiation, in the medium, and L is the distance between the first and second reflective layers. Nodes are located at distances d=n*λ/2 from the reflective layers.

According to at least one embodiment or configuration, the n-doped or first semiconductor region has a greater vertical extension than the p-doped or second semiconductor region. The vertical extension is determined, for example, parallel to a vertical direction. For example, the vertical extension of the n-doped or first semiconductor region can be n*λ/2, while the vertical extension of the p-doped or second semiconductor region is as small as possible and can be approximately λ/4.

Due to the lower vertical extension of the p-doped or second semiconductor region, absorption losses can be reduced. The first connecting layer can directly adjoin the p-doped or second semiconductor region of the first semiconductor layer stack and improve current spreading in the p-doped or second semiconductor region.

According to at least one embodiment or configuration, the first reflective layer comprises alternately arranged layers of a higher and a lower refractive index. For example, the first reflective layer is a Bragg mirror. The first reflective layer can contain semiconductor materials, for example alternately arranged layers of GaN and AlInN. It is also possible that the first reflective layer contains dielectric materials.

Furthermore, the second reflective layer can comprise alternately arranged layers of a higher and a lower refractive index and contain dielectric materials. For example, the second reflective layer is a Bragg mirror. For example, alternately arranged layers of titanium oxide or hafnium oxide and niobium oxide are suitable for the second reflective layer.

According to at least one embodiment or configuration, the laser diode component comprises a third reflective layer which is arranged on a side of the second reflective layer facing away from the first reflective layer. For example, the third reflective layer can be a metal layer. Metals with a comparatively high reflectivity, such as Au or Ag, are suitable for the third reflective layer. The third reflective layer is intended to improve the reflectivity on a side of the laser diode component opposite the radiation outcoupling side.

According to at least one embodiment or configuration, the laser diode component comprises a contact layer which is arranged between the second semiconductor layer stack and the second reflective layer. The contact layer can be provided for electrical contacting of the laser diode component. TCOs, for example, can be considered for the contact layer.

According to at least one embodiment or configuration, the laser diode component comprises at least one current confinement region which is arranged between the second reflective layer and the first semiconductor layer stack. The at least one current confinement region delimits a current flow to a defined aperture. For example, the current confinement region may be an etched region of one of the two connecting layers or an etched region of a semiconductor region adjacent to the connecting region. Furthermore, the at least one current confinement region can be a dielectric layer with a defined aperture.

According to at least one embodiment or configuration, the laser diode component comprises a carrier element on which the first and second semiconductor layer stacks are arranged, the second semiconductor layer stack being arranged between the carrier element and the first semiconductor stack. The carrier element is intended, for example, to stabilize the first and second semiconductor layer stacks instead of the at least one removed growth substrate. The carrier element can be, for example, a semiconductor substrate, such as a GaN, Si or Ge substrate, a metal carrier, such as of Ni, or a ceramic carrier.

According to at least one embodiment or configuration, the first semiconductor layer stack is arranged on a growth substrate which is located on a side of the first semiconductor layer stack facing away from the carrier element.

According to at least one embodiment or configuration, the laser diode component comprises a cover layer which laterally surrounds the second reflective layer. The cover layer can be provided for cooling the laser diode component. Materials with comparatively high heat conductivity, such as Cu or Au, are suitable for the cover layer.

The method described below is suitable for the production of at least one laser diode component of the above-mentioned type. Features described in connection with the laser diode component can therefore also be used for the method and vice versa.

According to at least one embodiment of a method for producing at least one laser diode component of the above type, the method comprises the following steps:
providing a first semiconductor layer sequence for producing at least one first semiconductor layer stack,
applying a first initial connecting layer to the first semiconductor layer sequence for producing at least one first connecting layer of a connecting region,
providing a second semiconductor layer sequence for producing at least one second semiconductor layer stack,
applying a second initial connecting layer to the second semiconductor layer sequence for producing at least one second connecting layer of a connecting region, wherein the first semiconductor layer sequence and the second semiconductor layer sequence are connected to each other by means of the first and second initial connecting layers,
providing a first initial reflective layer and a second initial reflective layer for producing at least one resonator.

According to at least one embodiment or configuration of the method, the first semiconductor layer sequence is provided on a first growth substrate. For example, the first growth substrate is a semiconductor substrate, such as a GaN substrate. Single layers contained in the first semiconductor layer sequence can be epitaxially grown on the first growth substrate.

According to at least one embodiment or configuration, the first initial connecting layer is applied on a side of the first semiconductor layer sequence facing away from the first growth substrate. TCOs, for example, can be used for the first initial connecting layer, as for the first connecting layer, which is produced from the first initial connecting layer.

According to at least one embodiment or configuration, the first initial reflective layer is grown on the first growth substrate between the first semiconductor layer sequence and the first growth substrate. Initially, the first initial reflective layer can therefore be grown on the first growth substrate. Subsequently, the first semiconductor layer sequence can be grown on the first initial reflective layer. Like the first reflective layer, which is produced from the first initial reflective layer, the first initial reflective layer can be formed from alternately arranged layers of a higher and a lower refractive index. Semiconductor materials are suitable for epitaxial production, wherein the first initial reflective layer can be formed, for example, from alternately arranged layers of GaN and AlInN.

Alternatively, the first initial reflective layer can be applied to the first semiconductor layer sequence and formed from different dielectric layers with different refractive indices. Before the first initial reflective layer is deposited on the first semiconductor layer sequence, the first growth substrate can be removed. A sacrificial layer can be arranged between the first growth substrate and the first semiconductor layer sequence and be removed during the removal of the first growth substrate from the first semiconductor layer sequence, for example by an electrochemical process. The first growth substrate can be removed after the first and second semiconductor layer sequences have been connected, with the first initial reflective layer being applied to the first semiconductor layer sequence on the side of the removed growth substrate.

According to at least one embodiment or configuration, the second semiconductor layer sequence is provided or grown on a second growth substrate. For example, the second growth substrate is a semiconductor substrate, such as a GaN substrate. Single layers contained in the second semiconductor layer sequence can be grown epitaxially on the second growth substrate.

According to at least one embodiment or configuration, the second growth substrate is removed after arrangement of the second semiconductor layer sequence on a carrier. A sacrificial layer may be arranged between the second growth substrate and the second semiconductor layer sequence and be removed during the removal of the second growth substrate from the second semiconductor layer sequence, for example by an electrochemical process. The carrier can be, for example, a semiconductor substrate, such as a GaN, Si or Ge substrate, a metal carrier, such as Ni, or a ceramic carrier. The carrier element of the laser diode component is formed from the carrier.

According to at least one embodiment or configuration, the second initial connecting layer, from which the second connecting layer is produced, is applied to the second semiconductor layer sequence on the side of the removed second growth substrate. As for the second connecting layer, TCOs, for example, can be considered for the second initial connecting layer.

According to at least one embodiment or configuration, the second initial reflective layer is applied on a side of the second semiconductor layer sequence facing away from the second growth substrate. This step is carried out, for example, before the second growth substrate is removed.

As mentioned above, the semiconductor layer sequences can be mechanically connected to each other by wafer bonding, for example when using TCO for the initial connecting layers. This realizes an efficient method for the production of laser diode components.

The laser diode components are particularly suitable for AR (Augmented Reality) applications, for applications in material processing, for LIDAR (Light Detection And Ranging, also known as Light Imaging, Detection And Ranging) systems and for use in hard disks, CD-ROM and Blu-ray or optical data transmission.

Further advantages, advantageous embodiments and further developments will become apparent from the exemplary embodiments described below in conjunction with the figures.

### BRIEF DESCRIPTION OF THE DRAWINGS

In the figures:

FIGS. 1A and 1B as well as 2A to 2C show various method steps of a method according to an exemplary embodiment for producing at least one laser diode component,

FIGS. 3 and 4 show cross-sectional views of laser diode components according to various exemplary embodiments,

FIGS. 5A to 5D show various method steps of a method according to a further exemplary embodiment for producing at least one laser diode component,

FIGS. 6 to 9 show cross-sectional views of laser diode components according to various exemplary embodiments.

### DETAILED DESCRIPTION

In the exemplary embodiments and figures, identical, similar or similarly acting elements can each be provided with the same reference signs. The elements shown and their relative sizes are not necessarily to be regarded as true to scale;

rather, individual elements may be shown in exaggerated size for better visualization and/or understanding.

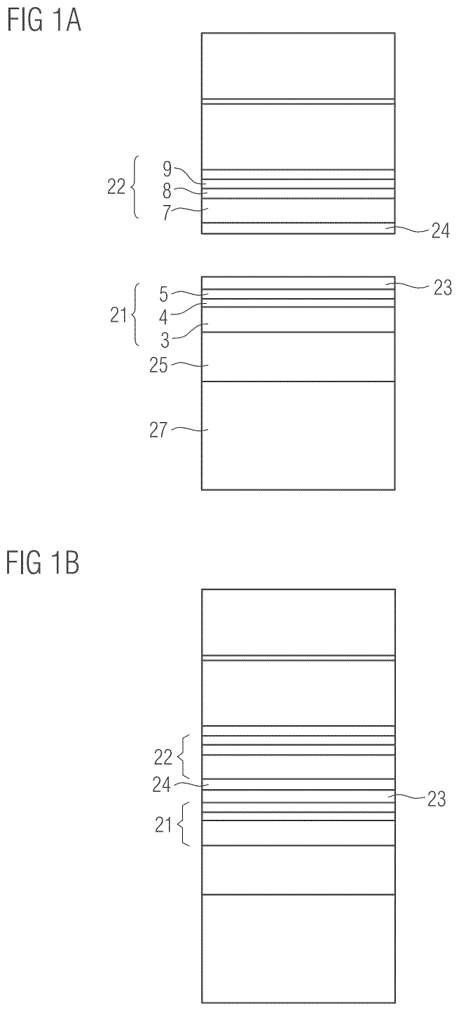

FIGS. 1A and 1B as well as 2A to 2C are used to describe an exemplary embodiment of a method for producing at least one laser diode component.

The method comprises providing a first semiconductor layer sequence 21 for producing at least one first semiconductor layer stack comprising a first semiconductor region 3 of a first conductivity type, an active zone 4 and a second semiconductor region 5 of a second conductivity type (see FIG. 1A, lower part). As already mentioned above, materials based on arsenide, phosphide or nitride compound semiconductors, for example, can be considered for the semiconductor regions 3, 4, 5 or single layers of the semiconductor layer stack or the semiconductor layer sequence 21.

The first semiconductor layer sequence 21 is provided on a first growth substrate 27, for example a GaN substrate. For example, the semiconductor layer sequence 21 can be epitaxially grown on the first growth substrate 27.

Furthermore, the method comprises providing or producing a first initial reflective layer 25, from which a first reflective layer is formed, which forms part of a resonator in the finished laser diode component. According to the first exemplary embodiment, the first initial reflective layer 25 is an epitaxial layer which may comprise a plurality of alternately arranged layers of a higher and a lower refractive index, wherein the initial reflective layer 25 is grown on the first growth substrate 27 between the first semiconductor layer sequence 21 and the first growth substrate 27. For example, the alternately arranged layers are formed from GaN and AlInN.

On a side of the first semiconductor layer sequence 21 facing away from the first growth substrate 27, a first initial connecting layer 23 for producing at least one first connecting layer is applied to the first semiconductor layer sequence 21. As already mentioned above, the first initial connecting layer 23 can be formed from TCO. The production method for the first initial connecting layer 23 may be chemical vapor deposition, for example.

Furthermore, the method comprises providing a second semiconductor layer sequence 22 for producing at least one second semiconductor layer stack comprising a first semiconductor region 7 of a first conductivity type, an active zone 8 and a second semiconductor region 9 of a second conductivity type (see FIG. 1A, upper part). As for the first semiconductor layer stack or the first semiconductor layer sequence 21, materials based on arsenide, phosphide or nitride compound semiconductors, for example, can be considered for the semiconductor regions 7, 8, 9 or single layers of the second semiconductor layer stack or the second semiconductor layer sequence 22.

In addition, the method comprises applying a second initial connecting layer 24 to the second semiconductor layer sequence 22 for producing at least one second connecting layer (see FIG. 1A, upper part). Analogous to the first initial connecting layer 23, the second initial connecting layer 24 can also be formed from TCO. Chemical vapor deposition, for example, can also be considered as a production method for the second initial connecting layer 24.

In a further step, the first semiconductor layer sequence 21 and the second semiconductor layer sequence 22 are connected to each other by means of the first and second initial connecting layers 23, 24 (see FIG. 1B). This can be done by wafer bonding if, for example, the two initial connecting layers 23, 24 are formed from TCO. This realizes an efficient method for producing laser diode components.

In connection with FIGS. 2A to 2C, method steps are described which may precede the method step shown in FIG. 1A and relate to the provision of the second semiconductor layer sequence 22, the application of the second initial connecting layer 24, and the provision of a second initial reflective layer 26.

The second semiconductor layer sequence 22 is initially provided on a second growth substrate 28, for example a GaN substrate. The second semiconductor layer sequence 22 may be epitaxially grown on the growth substrate 28. A sacrificial layer 29 is arranged between the second growth substrate 28 and the second semiconductor layer sequence 22 (see FIG. 2A). For example, the sacrificial layer 29 can be epitaxially grown on the second growth substrate 28.

A second initial reflective layer 26 for producing a part of a resonator of the finished laser diode component is applied on a side of the second semiconductor layer sequence 22 facing away from the second growth substrate 28. For example, the second initial reflective layer 26 may be formed of alternately arranged layers of a higher and a lower refractive index, for which dielectric materials may be used. For example, the layers can be formed alternately from titanium oxide or hafnium oxide and niobium oxide.

Furthermore, a third initial reflective layer 30 for producing a third reflective layer is applied on a side of the second initial reflective layer 26 facing away from the second growth substrate 28. For example, the third initial reflective layer 30 can be a metal layer. Metals with comparatively high reflectivity, for example Au or Ag, are suitable for the third initial reflective layer 30.

Subsequently, a carrier 31 is arranged on a side of the second semiconductor layer sequence 22 facing away from the growth substrate 28, in particular on a side of the third initial reflective layer 30 facing away from the growth substrate 28. The carrier 31 may, for example, be a semiconductor substrate, such as a GaN, Si or Ge substrate, a metal carrier, such as of Ni, or a ceramic carrier (see FIG. 2B).

Subsequently, the second growth substrate 28 is removed from the second semiconductor layer sequence 22 by removing the sacrificial layer 29. For example, the sacrificial layer 29 can be removed by an electrochemical process (see FIG. 2B). Thin-film technology is therefore used to produce the second layer stack.

The second initial connecting layer 24 is applied to the second semiconductor layer sequence 22 on the side of the removed second growth substrate 28 (see FIG. 2C).

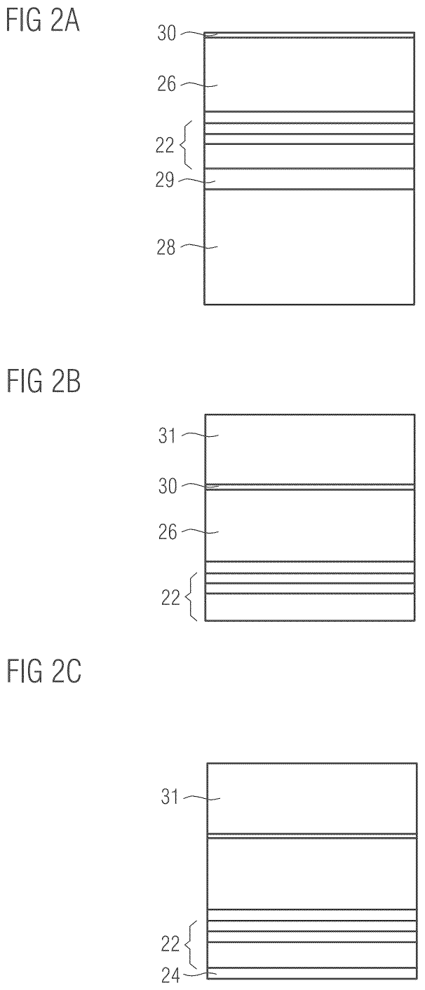

With reference to FIG. 3, an exemplary embodiment of a laser diode component 1 is described, which can be produced using the method described in connection with FIGS. 1A and 1B as well as 2A to 2C. The laser diode component 1 is a VCSEL.

The laser diode component 1 comprises a first semiconductor layer stack 2, which comprises a first semiconductor region 3 of a first conductivity type, a first active zone 4 for emitting a first laser radiation S1 having a first wavelength or a first wavelength spectrum λ1, and a second semiconductor region 5 of a second conductivity type.

Furthermore, the laser diode component 1 comprises a second semiconductor layer stack 6, which comprises a first semiconductor region 7 of a first conductivity type, a second active zone 8 for emitting a second laser radiation S2 having a second wavelength or a second wavelength spectrum λ2, and a second semiconductor region 9 of a second conductivity type, wherein the first semiconductor layer stack 2 follows the second semiconductor layer stack 6 in a main emission direction H1. For example, the main emission direction H1 runs parallel to a vertical direction V and antiparallel to a growth direction in which the semiconductor regions 3, 4, 5 and 7, 8, 9 are grown on top of each other.

The first semiconductor regions 3, 7 can be n-doped or n-conducting semiconductor regions, and the second semiconductor regions 5, 9 can be p-doped or p-conducting semiconductor regions. This means that a pn-pn structure is realized in the laser diode component 1 in the main emission direction H1. However, it is also possible for the laser diode component 1 to have an np-np structure.

The laser diode component 1 comprises a resonator 13, which comprises a first reflective layer 14 and a second reflective layer 15, wherein the first reflective layer 14 is arranged on a side of the first semiconductor layer stack 2 facing away from the second semiconductor layer stack 6, and the second reflective layer 15 is arranged on a side of the second semiconductor layer stack 6 facing away from the first semiconductor layer stack 2. The reflective layers 14, 15 correspond in their composition to the initial reflective layers 25, 26 from which they are produced, and can accordingly be formed multilayered from semiconductor materials or dielectric materials. In particular, the reflective layers 14, 15 are Bragg mirrors.

The first reflective layer 14 is arranged on a radiation outcoupling side of the laser diode component 1 and has a lower reflectivity than the second reflective layer 15 arranged on a side opposite the radiation outcoupling side. The first and the second laser radiation S1, S2 are preferably to be understood as coherent radiation in the fundamental mode of the resonator 13. The first and the second laser radiation S1, S2 can have similar or identical wavelengths or similar or identical wavelength spectra. In other words, λ1 can be approximately equal to λ2. The value range for λ1 and λ2 is, for example, in the short-wave, visible spectral range.

On a side of the second reflective layer 15 facing away from the first reflective layer 14, a third reflective layer 18 is arranged to improve the reflectivity on a side of the laser diode component 1 opposite the radiation outcoupling side. The reflective layer 18 corresponds in its composition to the third initial reflective layer 30, from which it is produced, and can accordingly be a metal layer, for which metals with comparatively high reflectivity, for example Au or Ag, are suitable.

Between the first and second semiconductor layer stacks 2, 6, the laser diode component 1 comprises an electrically conductive connecting region 10, which comprises a first electrically conductive connecting layer 11 and a second electrically conductive connecting layer 12, the first connecting layer 11 being applied to the first semiconductor layer stack 2 and the second connecting layer 12 being applied to the second semiconductor layer stack 6. The semiconductor layer stacks 2, 6 are not monolithically integrated, but are separate bodies which are mechanically connected to one another by means of the connecting region 10.

Furthermore, the semiconductor layer stacks 2, 6 are electrically conductively connected to each other by means of the connecting region 10. The connecting region 10 is free of a tunnel contact. This makes it possible to avoid the voltage drop that usually occurs at a tunnel contact. The connecting layers 11, 12 correspond in their composition to the initial connecting layers 23, 24, from which they are produced, and can contain TCO accordingly.

A vertical extension a1 of the n-doped or first semiconductor regions 3, 7 can be greater than a vertical extension a2 of the p-doped or second semiconductor regions 5, 9. The vertical extension is determined parallel to the vertical direction V. A reduction in the vertical extension a2 of the p-doped or second semiconductor regions 5, 9 is possible due to the connecting region 10, which ensures an advantageous electrical connection of the semiconductor layer stacks 2, 6. Furthermore, the connecting region 10 ensures a distance between the active zones 4, 8, so that better heat dissipation is possible in the laser diode component 1 than with monolithically integrated semiconductor layer stacks.

To regulate the current impression in the semiconductor layer stacks 2, 6, the laser diode component 1 comprises a first current confinement region 16A with a defined aperture λ1, which is arranged in the connecting region 10. The current confinement region 16A may, for example, be an etched region of the first and/or second connecting layer(s) 11, 12. Alternatively, the current confinement region 16A may be a dielectric layer. The current confinement region 16A confines the current flow to the aperture λ1.

In addition, the laser diode component 1 comprises a second current confinement region 16B arranged between the second reflective layer 15 and the second semiconductor layer stack 6. The second current confinement region 16B may, for example, be an etched region of a contact layer 19. Alternatively, the current confinement region 16B may be a dielectric layer. The current confinement region 16B confines the current flow to the aperture A2, which may coincide with the aperture λ1.

The laser diode component 1 further comprises a carrier element 17 on which the first and second semiconductor layer stacks 2, 6 are arranged, the second semiconductor layer stack 6 being arranged between the carrier element 17 and the first semiconductor stack 2. The carrier element 17 corresponds in its material composition to the carrier 31, from which it is produced.

In this exemplary embodiment, the first growth substrate 27 remains in the laser diode component 1 and is arranged on a side of the first semiconductor layer stack 2 facing away from the carrier element 17. During operation, the first and the second laser radiation S1, S2 are coupled out of the laser diode component 1 through the growth substrate 27. However, it is also conceivable that the laser diode component 1 is bi-directionally emitting, with part of the first and the second laser radiation S1, S2 being additionally coupled out on the side of the carrier element 17, so that a further main emission direction is essentially antiparallel to the main emission direction H1.

As can be seen from FIG. 3, the semiconductor layer stacks 2, 6 have a larger cross-section than the first reflective layer 14 or the growth substrate 27, so that the semiconductor layer stacks 2, 6 each have an edge region 2A, 6A laterally projecting beyond the first reflective layer 14 or the growth substrate 27. “Lateral” here means parallel to a plane spanned by a first lateral direction E1 and a second lateral direction arranged perpendicular to the first direction E1, the vertical direction V being arranged perpendicular to the lateral directions. A first contact element 32, which forms a first electrode of the laser diode component 1, is arranged on the edge region 2A of the first semiconductor layer stack 2.

Furthermore, the semiconductor layer stacks 2, 6 have a smaller cross-section than the carrier element 17 or the second reflective layer 15 and the contact layer 19, so that these each have an edge region 17A, 15A, 19A which projects laterally beyond the semiconductor layer stacks 2, 6. A second contact element 33, which forms a second electrode of the laser diode component 1, is arranged on the edge region 19A of the contact layer 19. The semiconductor layer stacks 2, 6 are connected in series.

In the resonator 13, the resonance condition is fulfilled in particular if n*λ1/2=L and n*λ2/2=L, where n is an integer and L is the resonator length or the distance between the first and second reflective layers 14, 15. Nodes are located at distances d1=n*λ1/2 or d2=n*λ2/2 from the reflective layers 14, 15.

The connecting region 10 is arranged at a node. This allows the absorption of the laser radiation S1, S2 to be reduced in the connecting region 10.

For example, the vertical extension a1 of the n-doped or first semiconductor regions 3, 7 can be n*λ1/2 or n*λ2/2, while the vertical extension a2 of the p-doped or second semiconductor regions 5, 9 is as small as possible and can be approximately λ1/4 or λ2/4. The vertical extension a2 can assume values of at most 100 nm, preferably at most 50 nm, particularly preferably at most 20 nm. The connecting layers 11, 12 can have the same thickness as the second semiconductor regions 5, 9.

Further layers, for example dielectric layers, can be arranged between the reflective layers 14, 15 and the respective semiconductor layer stacks 2, 6 facing them in order to adjust the resonator length L so that the resonance condition is fulfilled.

The laser diode component 1 with the plurality of semiconductor layer stacks 2, 6 or active zones 4, 8, which are connected to each other by means of the electrically conductive connecting region 10, has a better output power than a laser diode component with a single active zone or with active zones that are electrically connected to each other by a tunnel contact.

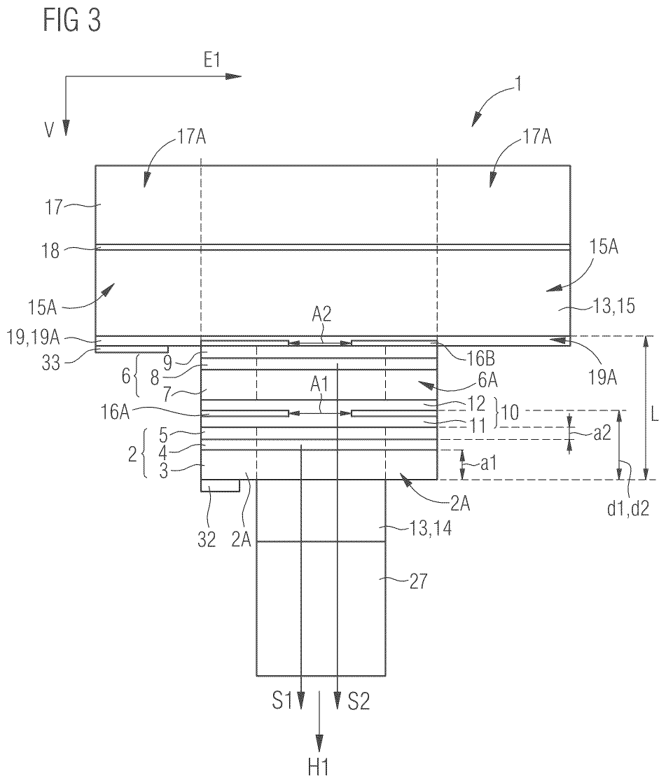

With reference to FIG. 4, another exemplary embodiment of a laser diode component 1 is described, which can be manufactured by means of the method described in connection with FIGS. 1A and 1B as well as 2A to 2C.

The laser diode component 1 comprises a cover layer 20, which laterally surrounds the second reflective layer 15. The cover layer 20 replaces the separated edge region 15A of the second reflective layer 15 (see FIG. 3). The cover layer 20 is intended to improve the cooling of the laser diode component 1. Materials with comparatively high heat conductivity, such as Cu or Au, are suitable for the cover layer 20.

In addition, the laser diode component 1 can have all the features, properties and advantages mentioned in connection with the other exemplary embodiments.

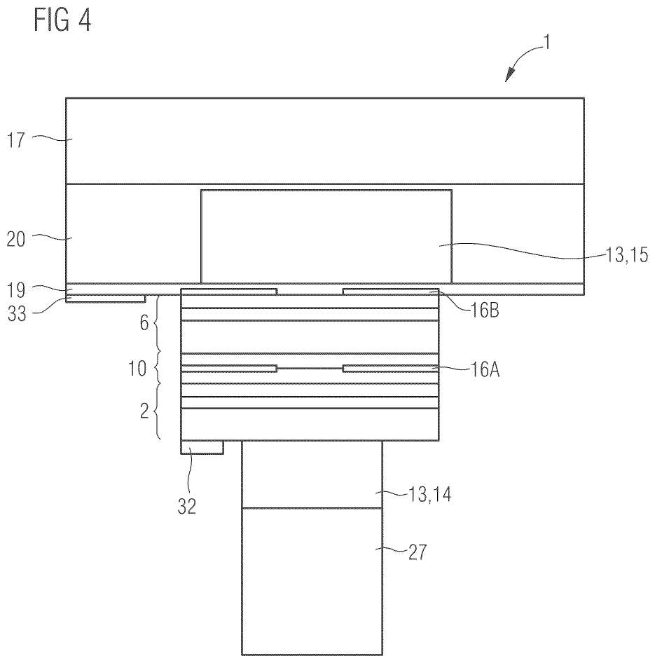

With reference to FIGS. 5A to 5D, a further exemplary embodiment of a method for producing at least one laser diode component is described.

Here, a first semiconductor layer sequence 21 is provided on a first growth substrate 27, wherein a sacrificial layer 29 is arranged between the first semiconductor layer sequence 21 and the first growth substrate 27. Furthermore, a second semiconductor layer sequence 22 is provided on a carrier 31 (see FIG. 5A). The provision of the second semiconductor layer sequence 22 may comprise the method steps explained in more detail in connection with FIGS. 2A to 2C.

The semiconductor layer sequences 21, 22 are mechanically and electrically conductively connected to one another by means of a first and a second initial connecting layer 23, 24, the first initial connecting layer 23 being arranged on a side of the first semiconductor layer sequence 21 facing away from the first growth substrate 27 and the second initial connecting layer 24 being arranged on a side of the second semiconductor layer sequence 22 facing away from the carrier 31 (cf. FIG. 5B). The connecting can be carried out by means of wafer bonding (cf. the explanations relating to FIG. 1B).

After connecting the semiconductor layer sequences 21, 22, the first growth substrate 27 is removed, wherein the sacrificial layer 29 is cut through, for example by an electrochemical process (see FIG. 5C). Thin-film technology is therefore used to produce the first layer stack.

After removing the first growth substrate 27, a first initial reflective layer 25 is applied to the first semiconductor layer sequence 21 on the side of the removed growth substrate 27 (see FIG. 5D). The first initial reflective layer 25 can be formed from different dielectric layers with different refractive indices.

In addition, the method may have all the features, properties and advantages mentioned in connection with the further exemplary embodiments.

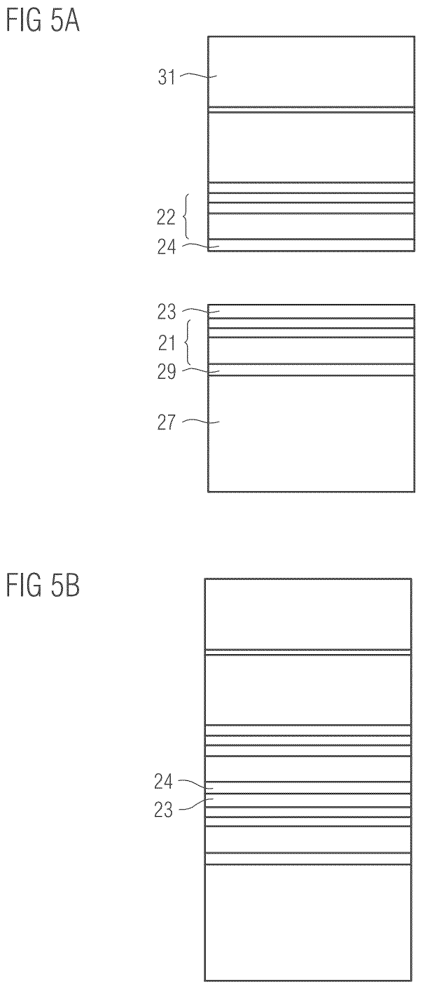

With reference to FIGS. 6 to 9, further exemplary embodiments of laser diode components 1 are described, which can be produced by means of the method described in connection with FIGS. 5A to 5D and each have a first reflective layer 14 made of dielectric material or dielectric materials. The first reflective layers 14 can have a higher reflectivity than the first reflective layers 14 formed from semiconductor material(s) of the exemplary embodiments shown in FIGS. 3 and 4.

Furthermore, the first semiconductor layer stacks 2 of the laser diode components 1 shown in FIGS. 6 to 9 are each essentially free of a growth substrate, so that, as in the case of the second semiconductor layer stacks 6, the first semiconductor layer stacks 2 are also thin-film structures.

Except for the different first reflective layer 14 and the missing growth substrate 27, the laser diode component 1 shown in FIG. 6 is designed like the laser diode component 1 shown in FIG. 3, so that the explanations given in connection with FIG. 3 apply accordingly.

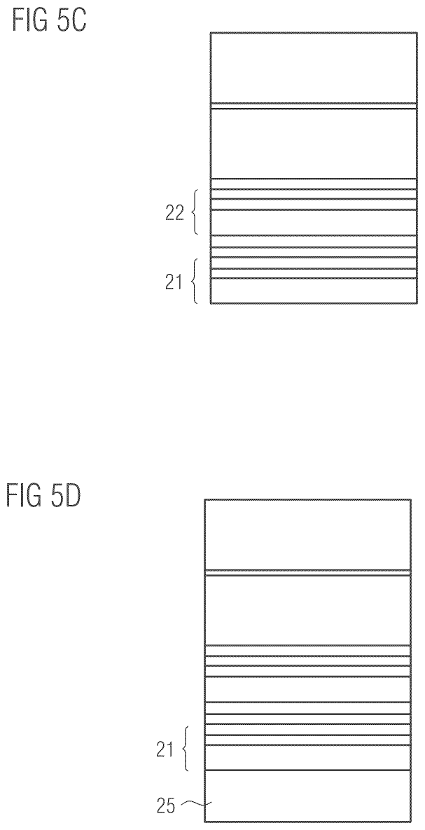

Except for the different first reflective layer 14 and the missing growth substrate 27, the laser diode component 1 shown in FIG. 7 is designed like the laser diode component 1 shown in FIG. 4, so that the explanations given in connection with FIG. 4 apply accordingly.

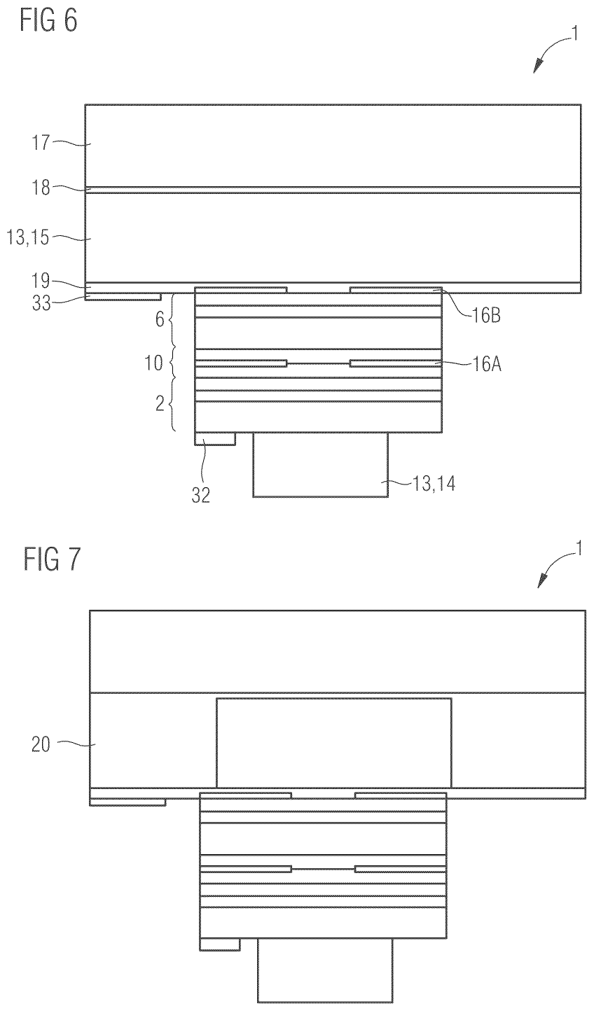

The laser diode component 1 shown in FIG. 8 lacks the third reflective layer 18 compared to the exemplary embodiment shown in FIG. 6.

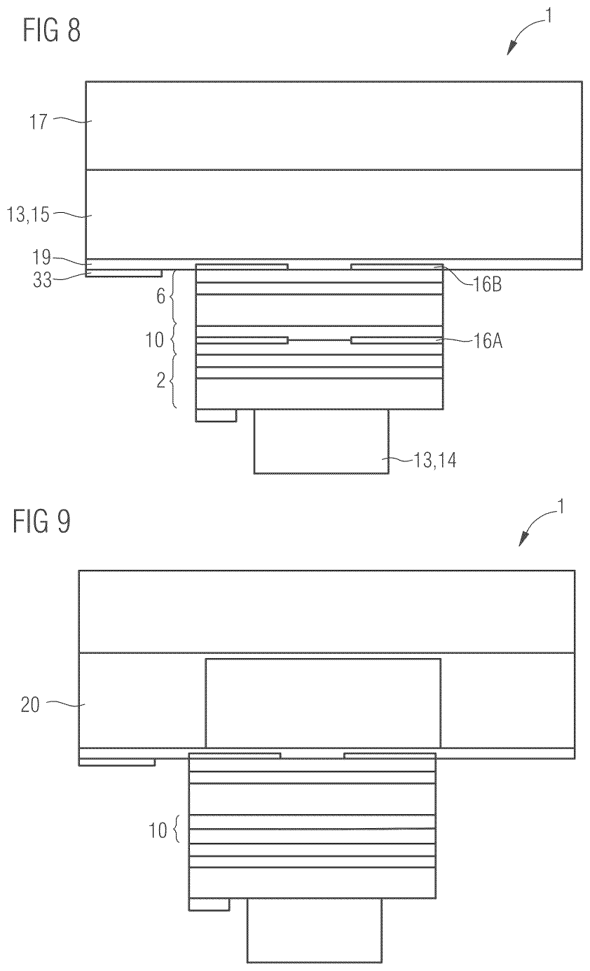

Compared to the exemplary embodiment shown in FIG. 7, the laser diode component 1 shown in FIG. 9 lacks the current confinement region 16A arranged in the connecting region 10.

In addition, the exemplary embodiments shown in FIGS. 6 to 9 can have all the features, properties and advantages mentioned in connection with the other exemplary embodiments.

The invention is not limited to the exemplary embodiments by the description based on these embodiments. Rather, the invention includes any new feature as well as any combination of features, which includes in particular any combination of features in the patent claims, even if this feature or combination itself is not explicitly stated in the patent claims or embodiments.

1. A laser diode component, comprising:
a first semiconductor layer stack which comprises a first active zone for emitting a first laser radiation,
a second semiconductor layer stack which comprises a second active zone for emitting a second laser radiation, the first and second semiconductor layer stacks following one another in a main emission direction,
a resonator which comprises a first reflective layer and a second reflective layer, the first reflective layer being arranged on a side of the first semiconductor layer stack facing away from the second semiconductor layer stack and the second reflective layer being arranged on a side of the second semiconductor layer stack facing away from the first semiconductor layer stack, and
an electrically conductive connecting region which is arranged between the first and second semiconductor layer stacks and comprises a first connecting layer and a second connecting layer, wherein
the first connecting layer is applied to the first semiconductor layer stack and the second connecting layer is applied to the second semiconductor layer stack.

2. The laser diode component according to claim 1, which is a VCSEL.

3. The laser diode component according to claim 1, wherein the first and second connecting layers each contain TCO.

4. The laser diode component according to claim 1, wherein the first and second semiconductor layer stacks each comprise a first semiconductor region of a first conductivity type and a second semiconductor region of a second conductivity type, the first and second semiconductor regions being arranged alternately in the main emission direction.

5. The laser diode component according to claim 1, wherein at least one of the two semiconductor layer stacks is essentially free of a growth substrate.

6. The laser diode component according to claim 1, wherein the connecting region is arranged at a node of a standing wave formed in the resonator.

7. The laser diode component according to claim 1, wherein the first reflective layer comprises alternately arranged layers of a higher and a lower refractive index and contains semiconductor materials or dielectric materials.

8. The laser diode component according to claim 1, wherein the second reflective layer comprises alternately arranged layers of a higher and a lower refractive index and contains dielectric materials.

9. The laser diode component according to claim 1, comprising at least one current confinement region which is arranged between the second reflective layer and the first semiconductor layer stack.

10. The laser diode component according to claim 1, comprising a carrier element on which the first and second semiconductor layer stacks are arranged, the second semiconductor layer stack being arranged between the carrier element and the first semiconductor stack.

11. The laser diode component according to claim 10, wherein the first semiconductor layer stack is arranged on a growth substrate which is located on a side of the first semiconductor layer stack facing away from the carrier element.

12. The laser diode component according to claim 1, wherein the semiconductor layer stacks are separate bodies.

13. The laser diode component according to claim 1, wherein the connecting region is free of a tunnel contact.

14. A method for producing at least one laser diode component according to claim 1, comprising:
providing a first semiconductor layer sequence for producing at least one first semiconductor layer stack,
applying a first initial connecting layer to the first semiconductor layer sequence for producing at least one first connecting layer of a connecting region,
providing a second semiconductor layer sequence for producing at least one second semiconductor layer stack,
applying a second initial connecting layer to the second semiconductor layer sequence for producing at least one second connecting layer of a connecting region, wherein the first semiconductor layer sequence and the second semiconductor layer sequence are connected to each other by means of the first and second initial connecting layers, and
providing a first initial reflective layer and a second initial reflective layer for producing at least one resonator.

15. The method according to claim 14, wherein the first semiconductor layer sequence is provided on a first growth substrate and the first initial connecting layer is applied on a side of the first semiconductor layer sequence facing away from the first growth substrate.

16. The method according to claim 15, wherein the first initial reflective layer is grown on the first growth substrate between the first semiconductor layer sequence and the first growth substrate.

17. The method according to claim 15, wherein the first growth substrate is removed after connecting the first and second semiconductor layer sequences and the first initial reflective layer is applied to the first semiconductor layer sequence on the side of the removed growth substrate.

18. The method according to claim 14, wherein the second semiconductor layer sequence is provided on a second growth substrate and the second growth substrate is removed after arranging the second semiconductor layer sequence on a carrier.

19. The method according to claim 18, wherein the second initial connecting layer is applied to the second semiconductor layer sequence on the side of the removed second growth substrate.

20. The method according to claim 18, wherein the second initial reflective layer is applied on a side of the second semiconductor layer sequence facing away from the second growth substrate.
